(19) United States
(12) Patent Application Publication
(10) Pub. No.: US 2015/0222311 A1
(43) Pub. Date: Aug. 6, 2015

(54) HOUSING FOR ELECTROSTATIC DISCHARGE PROTECTION OF A PORTABLE COMMUNICATION DEVICE

(71) Applicant: MOTOROLA SOLUTIONS ,INC., Schaumburg, IL (US)

(72) Inventors: Wooi Ping Teoh, Georgetown (MY); Weng Kong Hor, Butterworth (MY); Stephen D. Hunt, Cooper City, FL (US); Peter C. Jan, Butterworth (MY); Cheah Chan Kee, Gelugor (MY)

(21) Appl. No.: 14/424,875

(22) PCT Filed: Aug. 27, 2012
(86) PCT No.: PCT/MY2012/000238

§ 371 Date: Feb. 27, 2015

(51) Int. Cl. H04B 1/3827; H05K 9/00; H05F 1/00

(52) U.S. Cl. CPC H04B 1/3838; H05F 1/00; H05K 9/0079; H05K 9/005; H05K 9/0047

(57) ABSTRACT

A housing (100) provides electrostatic discharge protection and structural robustness for a portable communication device. A hybrid formation of an inner housing portion (102) composed a non-ESD material provides for robustness and an outer housing portion (104) formed of ESD material provides improved grounding.

### FIELD OF THE INVENTION

The present invention relates generally to communication devices and more particularly to electrostatic discharge protection of portable communication devices.

### BACKGROUND

Communication devices, such as portable two-way radios, are typically utilized in public safety communication environments, such as law enforcement, fire, rescue, security and the like. A two-way radio is typically housed within a plastic enclosure, and depending on the user interface requirements, the housing may offer a keypad, push-to-talk switch, control knobs, speaker grill and display. Plastic housings can be susceptible to electrostatic discharge, as the plastic material itself is unable to prevent ESD build-up. Radios having displays, keypads and other user-interface features tend to be more susceptible to ESD.

In hazardous environments, it is particularly important to limit the amount of ESD build up on the enclosure surface. This is important since electrostatic charge build up beyond a certain limit may result in a discharge, accompanied by a spark ignition which might potentially lead to an explosion. A conventional approach to mitigate surface ESD is to reduce the contact surface (serration) on polycarbonate enclosures. However, this approach is limited to surface ESD build up of only up-to 10 nano-coulombs (nC). Another approach to the aforementioned problems involves using an ESD material molded enclosure. However, these types of molded enclosures do not provide the level of robustness required by public safety communication products

Accordingly, there is a need for an improved approach to ESD protection for portable communication products operating in the public safety environment.

### BRIEF DESCRIPTION OF THE FIGURES

The accompanying figures where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is a housing for providing electrostatic discharge (ESD) protection in accordance with the various embodiments.

FIG. 2 is a portable communication device having the housing of FIG. 1 coupled thereto in accordance with the various embodiments.

FIG. 3 shows a bottom view of the housing and shows a view of the housing coupled to the communication device in accordance with the various embodiments.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in an improved housing providing electrostatic discharge (ESD) protection for a portable communication device. Accordingly, the components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

Briefly, there is provided herein a housing attachment formed of hybrid of conventional thermoplastic and ESD material to form a robust enclosure providing ESD protection. The proposed plastic enclosure comprises two components, wherein the inner component is made from a polycarbonate (PC) material which provides structural strength to the enclosure and the outer component which is made from an electrically conductive material to prevent electrostatic charge build up. Both, the inner and outer components may be formed using injection molding and bonded, or coupled using mechanical locking.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

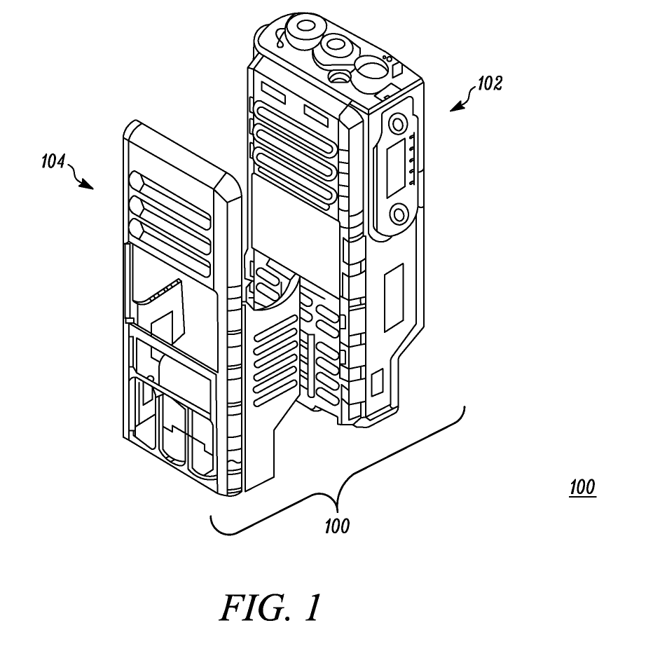

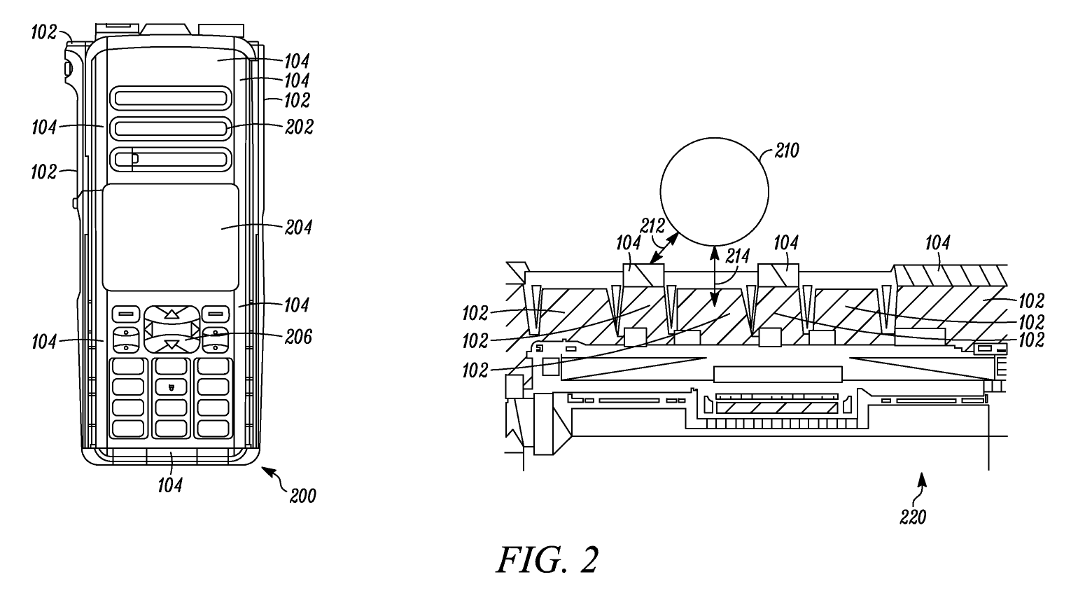

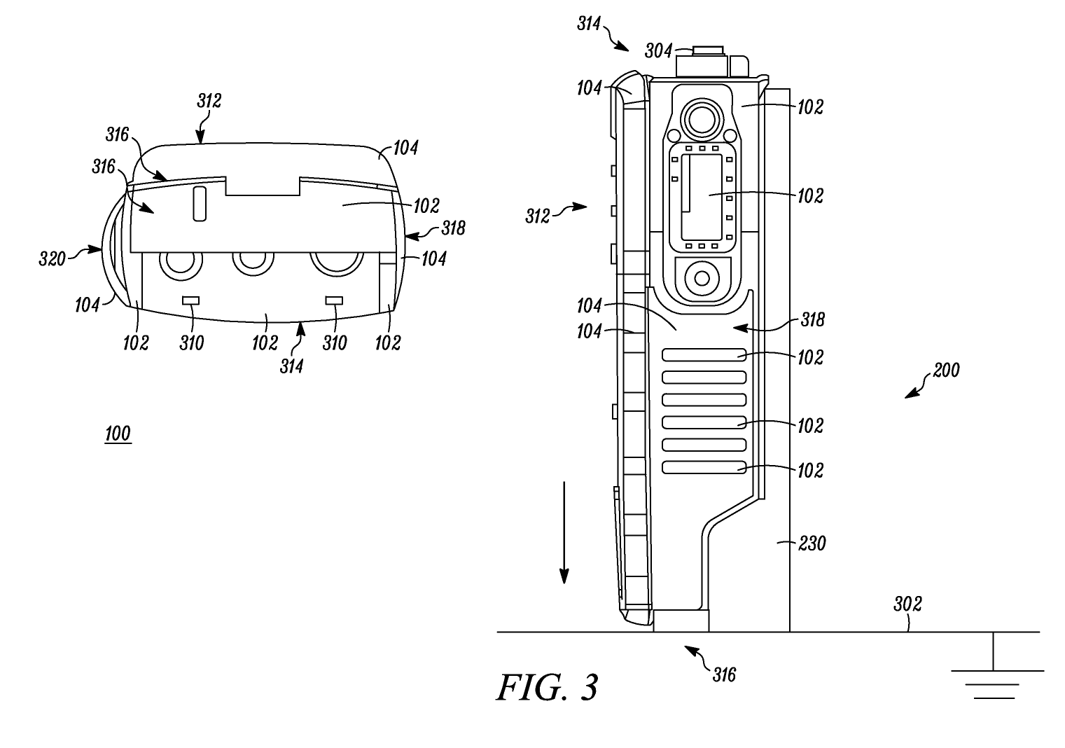

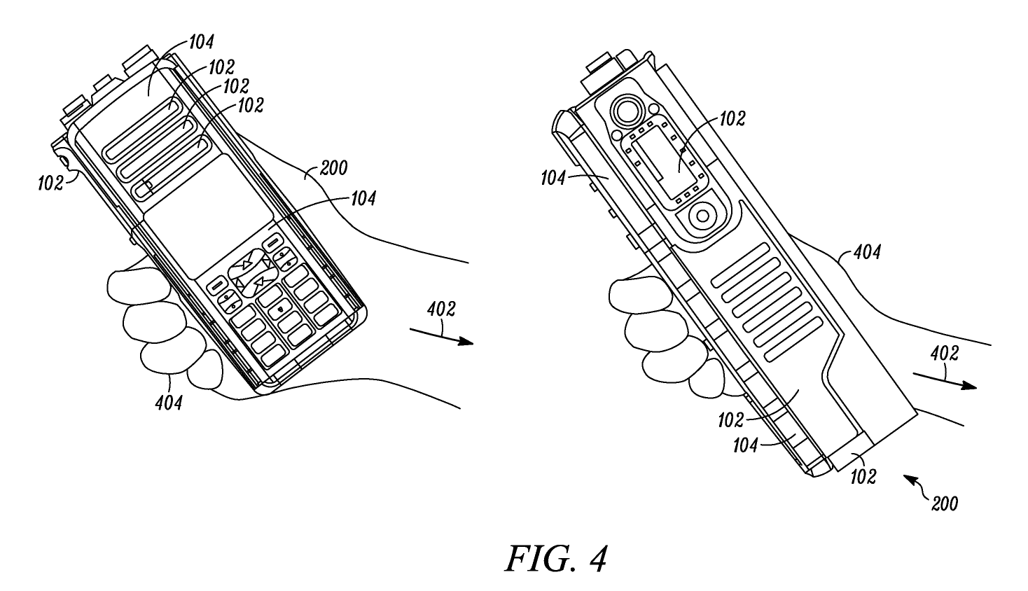

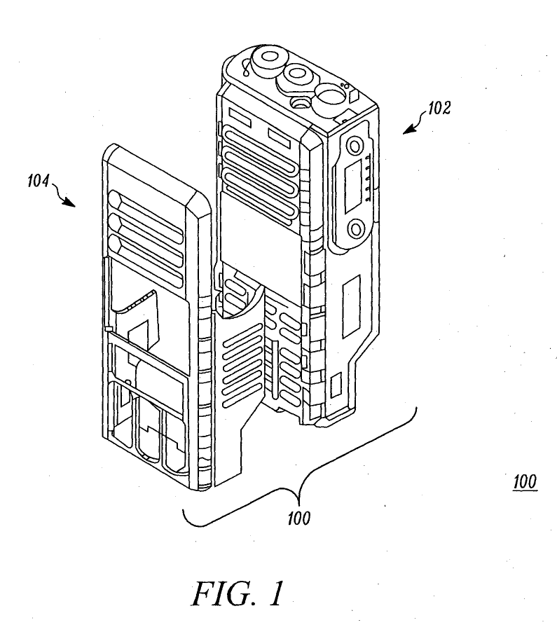

FIG. 1 is a housing 100 formed in accordance with the various embodiments. Housing 100 provides ESD protection and structural robustness for a portable communication device, such as a handheld radio. Housing 100 is formed of two housing portions, an inner housing portion 102 and an outer housing portion 104. The inner housing portion 102 is formed of a thermoplastic substrate. Thermoplastic substrates such as those formed of polycarbonate material compounds are appropriate for this type of housing. For example, an impact-modified polycarbonate copolymer alloy provides sufficient structural properties for enclosures utilized in the public safety market. In accordance with the various embodiments, the outer housing portion 104 is formed of an electrically conductive material to prevent electrostatic charge build-up. The ESD material used for outer portion 104 may be formed, for example, of a carbon-powder filled version of the substrate material used for the inner housing portion 102. The ESD material is selected to impart sufficient electrical conductivity so as to enable effective static dissipative performance in the molded housing 100. Both inner and outer portions 102, 104 are formed using an injection molding process.

The ESD and non-ESD material layers of housing 100 comprise apertures formed therein to accommodate access to a plurality of user interface features for a communication device, such as speaker grill, display, keypad and control knobs. The housing 100 provides a hybrid sheath of thermoplastic and ESD material to form an enclosure providing ESD protection to a portable handheld radio. Product safety directives have been established under various agencies and standards, such as Factory Mutual (FM) and ATmosphere EXplosible (ATEX) to address product safety. Devices operating under these directives or standards are also referred to as intrinsically safe devices. The housing 100 formed in accordance with the various embodiments satisfies ATEX requirements for ESD and robustness requirements for public safety communication products.

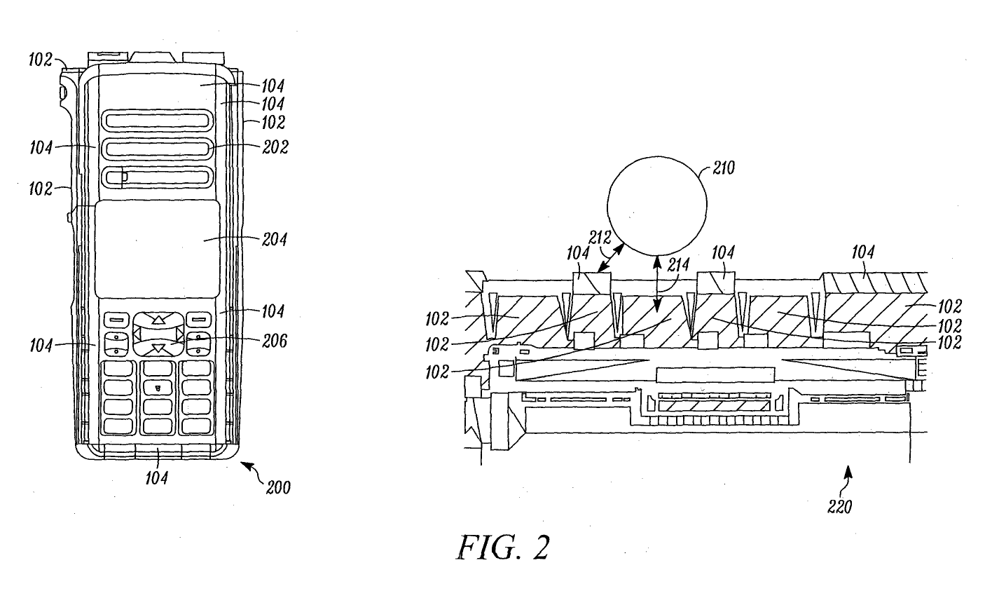

In accordance with the various embodiments, the inner and outer 102, 104 housing portions are bonded as a single unit, housing 100, and coupled to a portable communication device 200 as shown in FIG. 2. The inner and outer housing portions 102, 104 can be bonded by using a dual shot injection molding method. Alternatively, a locking mechanism may also be used to bond the inner and outer housing portions 102, 104. The inner housing portion 102 provides maximum coverage to the portable communication device 200, and the outer housing portion 104 provides maximum coverage to areas susceptible to ESD.

The electrically conductive material of the outer portion 104 protects the housing 100 from electrostatic buildup regardless of what type of charging environment the portable communication device 200 may be exposed to. For example, when the charge build-up is applied by rubbing or striking the surface of the portable communication device 200, the housing 100 protects the portable communication device from ESD.

The housing 100 formed in accordance with the various embodiments provides increased design flexibility by utilizing both ESD and non-ESD materials in an optimized form factor for portable communication devices, particularly those utilized in the public safety environment, such as handheld two-way radios.

FIG. 2 shows the portable communication device 200, such as portable two way radio, having speaker grill 202, display 204, and keypad 206, which are non-conductive areas of the portable communication device 200. The ESD and non-ESD material layers are cut out to accommodate these non-conductive surface areas 202, 204, 206 for user interface access. Hence, substantial portions of the non-conductive surface area (here speaker grill 202, display 204, and keypad 206) are surrounded by the conductive material of outer housing portion 104. Additionally, features such as the speaker grill 202, while cut-out in the outer housing portion 104 may still be covered (with appropriate porting) and protected by the inner housing non-ESD material portion 102 for increased ruggedness and protection of the speaker.

Referring to the cross-sectional view 220 of FIG. 2, there is shown a representation of a discharge probe 210 in proximity with the portable communication device 200 (a side portion of which is shown in cross section with radio components beneath). As seen this in the cross-sectional view 220, a distance 212 between the discharge probe 210 and the ESD material of outer housing portion 104 is shorter than the distance between the discharge probe 210 and the non-ESD material of inner housing portion 102. Thus, the ESD material of outer housing portion 104 is able to provide a separation distance to prevent discharge probe 210 approaching the non-ESD material of inner housing portion 102. The ESD accumulated on non-ESD material of inner housing portion 102 will get discharged through ESD material of outer housing portion 104. The discharge probe 210 is thus unable to collect a charge from the ESD material of outer housing portion 104 and therefore no spark is generated.

The housing 100, in accordance with the various embodiments, is formed of a hybrid of ESD and non-ESD material, to provide discharge protection and structural reliability. The hybrid from factor of housing 100 also lends itself well to utilizing contrasting colors which can be advantageous in the ruggedized public safety market. Hence, the ESD material may be formed of a first color and the non-ESD material may be formed of a second color.

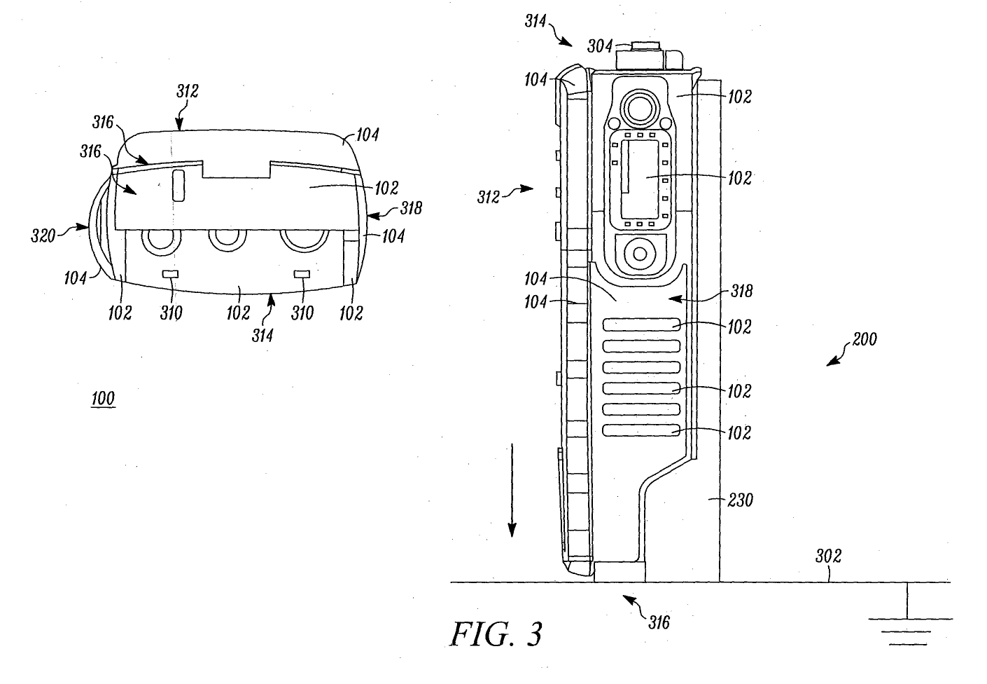

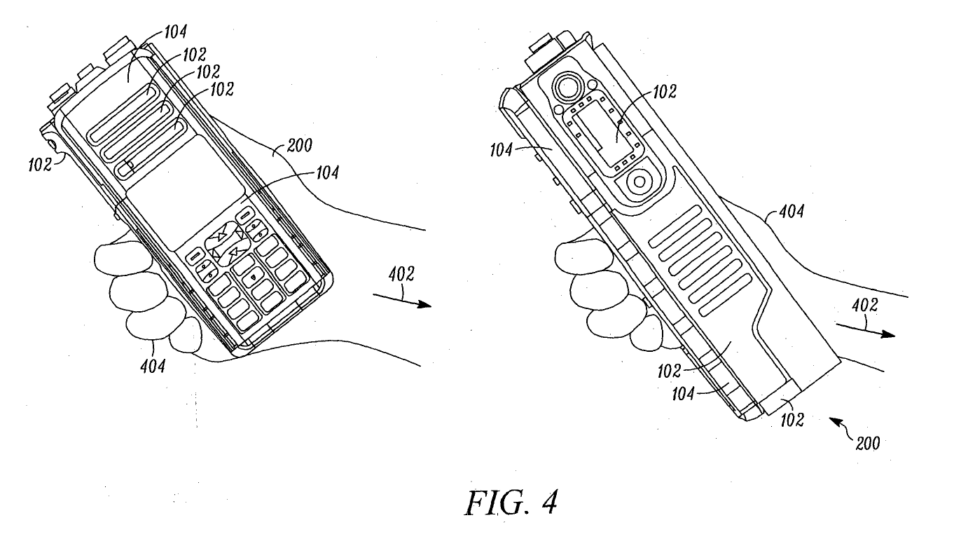

Referring to FIG. 3, a bottom view of the housing 100 is shown on the left, and a view of the housing 100 coupled to the portable communication device 200 is shown on the right in accordance with the various embodiments. Portable communication device 200 further comprises a battery 230 forming a back cover or back housing portion for the portable communication device. The battery 230 is formed of ESD material. When housing 100 is coupled to the portable communication device 200, the housing provides ESD material over major portions of the portable communication device's front, top, bottom and side surfaces thereby allowing the device to be grounded on to a ground base 302 in any direction.

The housing 100 formed of the hybrid sheath of ESD material and non-ESD material provides portions for front 312, top 314, bottom 316, and first and second sides 318, 320 to the portable communication device 200. In accordance with the various embodiments, the housing 100 is attachable and detachatable to and from the portable communication device (e.g. radio chassis and battery) thereby allowing the portable communication device to be serviced when needed. Housing 100 slides and snaps to the portable communication device 200. Retention features or recesses 310 molded in the interior of top surface 314 may be used to couple the housing 100 to the portable communication device 200. Other similar retention features or recesses (not shown) may be formed in the other surfaces 312, 316, 318, 320 of housing 100 for retention purposes to the portable communication device 200. As seen in FIG. 3, the portable communication device 200 is grounded immediately when the user places the housing 100 on a metal earth base 302 (via the bottom 316 of housing 100). In the event that the earth based metal 302 is not available, surface ESD protection is still achieved by grounding 402 through a user's human hand 404 as seen in FIG. 4.

Referring to FIGS. 2, 3, and 4, the portable communication device 200 formed and operating as a two-way radio provides user interface features comprising grill 202, display 204, keypad 206, and control knobs 304 in a robust and ESD protected environment. Prototypes of the housing 100 have been tested over a combination of surface ATEX and reliability testing including thermal endurance, chemical exposure, high humidity solar radiation, flammability , salt fog, and various drop tests. The prototypes of housing 100 have passed appropriate requirements for the public safety marked. Surface ESD assessments have shown no discharge. Thus, housing 100m formed in accordance with the various embodiments provides an advantage over serration type housings which tend to be susceptible to discharge (i.e. spark generation from the serrated housing).

Accordingly, in accordance with the various embodiments, there has been provided a housing for a portable communication device, such as a portable two-way radio, comprising an inner housing portion formed of non-ESD material and an outer housing portion formed of ESD material. The housing provides a protective sheath preventing electrostatic charge build-up via the ESD material and structural robustness via the non-ESD material. The non-serrated housing improves the ESD performance Portable handheld radio products utilized in the public safety communications environment, even those having displays and keypads can benefit greatly from the housing.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

We claim:

1. A housing, comprising:
an inner housing portion formed of non-electrostatic discharge (ESD) material; and
an outer housing portion formed of an ESD material, wherein the housing provides a protective sheath preventing electrostatic charge build-up via the ESD material and structural robustness via the non-ESD material.

2. The housing of claim 1, wherein the non-ESD material of the inner housing portion comprises a thermoplastic material, and the ESD material of the outer housing portion is overmolded to the non-ESD material.

3. The housing of claim 2, wherein the ESD material comprises a carbon-powder filled version non-ESD material.

4. The housing of claim 1, wherein the housing is attachable to and detachable from a portable radio.

5. A portable communication device, comprising:
a radio; and
a housing formed of a hybrid sheath of electrostatic discharge (ESD) material and non-ESD material, the hybrid sheath providing ESD protection to the radio.

6. The portable communication device of claim 5, wherein the housing is attachable and detachatable to and from the radio.

7. The portable communication device of claim 5, wherein the housing slides and snaps to the radio.

8. The portable communication device of claim 5, wherein the housing formed of the hybrid sheath of ESD material and non-ESD material covers portions of front, top, side, and bottom surfaces of the radio.

9. The portable communication device of claim 5, wherein the hybrid sheath of ESD and non-ESD material prevents ESD build-up and provides structural reinforcement to the radio.

10. The portable communication device of claim 5, wherein the non-ESD material is formed of polycarbonate compound, and the ESD material is formed of carbon-powder filled version of the ESD material.

11. The portable communication device of claim 5, wherein the housing is formed by dual shot injection molding the ESD material and non-ESD material.

12. The portable communication device of claim 5, wherein the ESD material is formed of a first color and the non-ESD material is formed of a second color.

13. The portable communication device of claim 5, wherein the portable communication device comprises a public safety radio.

14. The portable communication device of claim 5, wherein a back portion of the radio comprises a battery and the battery is covered in ESD material.

15. The portable communication device of claim 5, wherein the housing is a non-serrated housing.

16. The portable communication device of claim 5, wherein the housing formed of a hybrid sheath of ESD material and non-ESD material comprises apertures formed therein to accommodate a speaker grill, a display, and a keypad.

17. The portable communication device of claim 5, wherein the housing formed of the hybrid sheath provides an inner housing portion formed of the electrostatic discharge (ESD) material and an outer housing portion of formed of the non-ESD material.

18. The portable communication device of claim 17, wherein the hybrid sheath is snap-fitted to the radio via retention features molded in the non-ESD material of the inner housing portion.
